(19) United States
(12) Patent Application Publication
(10) Pub. No.: US 2026/0075819 A1
(43) Pub. Date: Mar. 12, 2026

(54) MANUFACTURING METHOD OF A MEMORY DEVICE

(71) Applicant: SK hynix Inc., Icheon-si Gyeonggi-do (KR)

(72) Inventors: Young Kyun KWEON, Icheon-si Gyeonggi-do (KR); Yang Bok LEE, Icheon-si Gyeonggi-do (KR); Yoon Joo LEE, Icheon-si Gyeonggi-do (KR); Sun Kak HWANG, Icheon-si Gyeonggi-do (KR); Dong Chul YOO, Icheon-si Gyeonggi-do (KR)

(73) Assignee: SK hynix Inc., Icheon-si Gyeonggi-do (KR)

(21) Appl. No.: 19/076,467

(22) Filed: Mar. 11, 2025

(30) Foreign Application Priority Data
Sep. 10, 2024 (KR) 10-2024-0123130

(51) Int. Cl. H10B 43/27

(52) U.S. Cl. CPC H10B 43/27

(57) ABSTRACT

A method of manufacturing a memory device includes forming an opening penetrating a stack structure, forming a channel layer including a first part and a second part, wherein the first part extends on an upper surface of the stack structure and the second part extends on an inner side surface of the opening, forming a protective layer on the first part of the channel layer, and etching a portion of the second part which is not covered by the protective layer so that the second part has a smaller thickness than the first part.

### CROSS-REFERENCE TO RELATED APPLICATION

The present application claims priority under 35 U.S.C. §119(a) to Korean patent application number 10-2024-0123130 filed on Sep. 10, 2024, in the Korean Intellectual Property Office, the entire contents of which application is incorporated herein by reference.

### BACKGROUND

### 1. Technical Field

Various embodiments of the present disclosure generally relate to a manufacturing method of a memory device, more particularly, to a method of manufacturing a memory device including a three-dimensional memory block.

### 2. Related Art

Memory devices may include non-volatile memory devices that retain stored data even in the absence of power supply. The non-volatile memory devices may be divided into two-dimensionally structured memory devices or three-dimensionally structured memory devices, depending on arrangements of memory cells of each of the non-volatile memory devices. Memory cells of a non-volatile memory device having a two-dimensional structure may be arranged in a single layer on a substrate. Memory cells of a non-volatile memory device having a three-dimensional structure may be stacked in a vertical direction to the substrate. Because integration density of the non-volatile memory device having the three-dimensional structure is greater than that of the non-volatile memory device having the two-dimensional structure, electronic devices including three-dimensionally structured non-volatile memory devices have recently been increasing.

### SUMMARY

According to an embodiment, a method of manufacturing a memory device may include forming an opening penetrating a stack structure, forming a channel layer including a first part and a second part, wherein the first part extends on an upper surface of the stack structure and has a first thickness, and the second part extends on an inner side surface of the opening and has a second thickness, forming a protective layer on the first part of the channel layer, and etching a portion of the second part so that the second part has a third thickness smaller than the second thickness, wherein the third thickness of the second part is less than the first thickness of the first part.

According to an embodiment, a method of manufacturing a memory device may include forming an opening penetrating a stack structure, forming a channel layer including a first part and a second part, wherein the first part extends on an upper surface of the stack structure and the second part extends on an inner side surface of the opening, forming a protective layer on the first part of the channel layer, and etching a portion of the second part which is not covered by the protective layer so that the second part has a smaller thickness than the first part.

### BRIEF DESCRIPTION OF THE DRAWINGS

FIG. 1 is a diagram illustrating a memory device according to an embodiment of the present disclosure;

FIG. 2 is a diagram schematically illustrating a memory device according to an embodiment of the present disclosure;

FIG. 3A is a plan view of a layout of a memory device according to an embodiment of the present disclosure;

FIG. 3B is a cross-sectional view of a memory device according to an embodiment of the present disclosure;

FIGS. 4A, 4B, 4C, 4D, 4E, 4F, 4G, 4H, and 4I are diagrams illustrating a method of manufacturing a memory device according to an embodiment of the present disclosure;

FIGS. 5A, 5B, 5C, 5D, 5E, and 5F are diagrams illustrating a method of manufacturing a memory device according to an embodiment of the present disclosure;

FIG. 6 is a diagram illustrating a memory card system to which a memory device according to an embodiment of the present disclosure is applied; and

FIG. 7 is a diagram illustrating a solid state drive (SSD) system to which a memory device according to an embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments of the present disclosure will be described in detail with reference to the accompanying drawings in order for those skilled in the art to be able to implement the technical spirit of the present disclosure.

Various embodiments are directed to a method of manufacturing a memory device capable of reducing the thickness of a channel layer included in a cell plug and the defects in a memory block.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

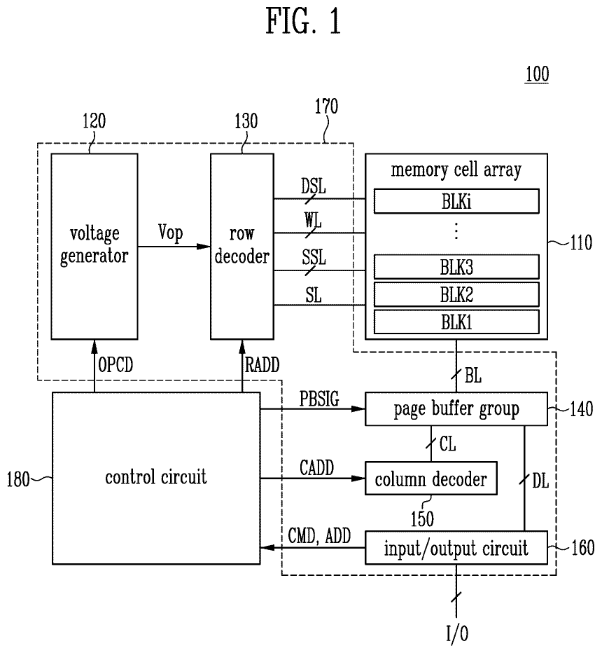

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

Each of the first to ith memory blocks BLK1 to BLKi may have a three-dimensional structure. Each of memory blocks having a three-dimensional structure may include memory cells stacked in a vertical direction on a substrate. The memory cells stacked in the vertical direction may respectively correspond to intersections of cell plugs included in the memory block and word lines. The degree of interference of adjacent memory cells in the vertical direction may be determined according to the thickness of a channel layer included in each cell plug. For example, as the thickness of the channel layer decreases, the interference (e.g., Z-interference) between the adjacent memory cells in the vertical direction may be reduced.

Each of the memory cells may store one-bit or two-or-more-bit data according to a program method. For example, a method in which one-bit data is stored in one memory cell is referred to as a single-level cell (SLC) method, and a method in which two-bit data is stored in one memory cell is referred to as a multi-level cell (MLC) method. A method in which three-bit data is stored in one memory cell is referred to as a triple-level cell (TLC) method, and a method in which four-bit data is stored in one memory cell is referred to as a quad-level cell (QLC) method. In addition, five-or-more-bit data may be stored in one memory cell.

The peripheral circuit 170 may be configured to perform a program operation that stores data in the memory cell array 110, a read operation that outputs data stored in the memory cell array 110, and an erase operation that erases data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 may be configured to generate program voltages, turn-on voltages, turn-off voltages, negative voltages, pre-charge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a selected memory block through the row decoder 130.

The program voltages may be applied to a selected word line among the word lines WL during a program operation, and may be used to increase threshold voltages of memory cells coupled to the selected word line. The turn-on voltages may be applied to the drain select lines DSL or the source select lines SSL, and may be used to turn on the drain select transistors or the source select transistors. The turn-off voltages may be applied to the drain select lines DSL or the source select lines SSL, and may be used to turn off the drain select transistors or the source select transistors. For example, the turn-off voltages may be set to 0 V. The pre-charge voltages may be higher than 0 V, and may be applied to the bit lines BL during a read operation. The verify voltages may be used during a verify operation to determine whether threshold voltages of selected memory cells have been increased to a target level. The verify voltages may be set to various levels according to the target level, and may be applied to the selected word line.

The read voltages may be applied to the selected word line during a read operation of the selected memory cells. For example, the read voltages may be set to various levels according to a program method of the selected memory cells. The pass voltages may be applied to unselected word lines among the word lines WL during a program or read operation, and may be used to turn on memory cells coupled to the unselected word lines. The erase voltages may be used during an erase operation to erase memory cells included in the selected memory block, and may be applied to the source line SL.

The row decoder 130 may be configured to transfer the operating voltages Vop to the drain select lines DSL, the word lines WL, the source select lines SSL, and the source line SL that are coupled to a memory block selected according to a row address RADD. For example, the row decoder 130 may be coupled to the voltage generator 120 through global lines, and may be coupled to the first to ith memory blocks BLK1 to BLKi through the drain select lines DSL, the word lines WL, the source select lines SSL, and the source line SL.

The page buffer group 140 may include page buffers (not shown) respectively coupled to the first to ith memory blocks BLK1 to BLKi. The page buffers (not shown) may be coupled to the first to ith memory blocks BLK1 to BLKi through the bit lines BL, respectively. During a read operation, the page buffers (not shown) may sense a current or a voltage of the bit lines BL that varies according to the threshold voltages of the selected memory cells and may store sensed data in response to page buffer control signals PBSIG.

The column decoder 150 may be configured to transfer data between the page buffer group 140 and the input/output circuit 160 in response to a column address CADD. For example, the column decoder 150 may be coupled to the page buffer group 140 through column lines CL and may transfer enable signals through the column lines CL. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transfer the command CMD and the address ADD, which are received from an external controller through the input/output lines I/O, to the control circuit 180, and may transfer data, which is received from the external controller through the input/output lines I/O, to the page buffer group 140. Alternatively, the input/output circuit 160 may output data transferred from the page buffer group 140 to the external controller through the input/output lines I/O.

The control circuit 180 may output at least one of the operation code OPCD, the row address RADD, the page buffer control signals PBSIG, and the column address CADD in response to the command CMD and the address ADD. For example, when the command CMD input to the control circuit 180 corresponds to a program operation, the control circuit 180 may control the peripheral circuit 170 to perform the program operation of a memory block selected by the address ADD. When the command CMD input to the control circuit 180 corresponds to a read operation, the control circuit 180 may control the peripheral circuit 170 to perform the read operation of the memory block selected by the address ADD and to output read data. When the command CMD input to the control circuit 180 corresponds to an erase operation, the control circuit 180 may control the peripheral circuit 170 to perform the erase operation of the selected memory block.

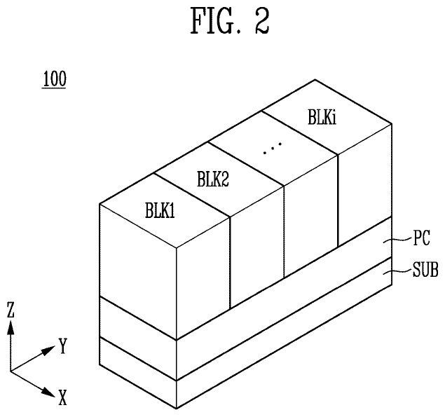

FIG. 2 is a diagram schematically illustrating the memory device 100 according to an embodiment of the present disclosure.

Referring to FIG. 2, the memory device 100 may include a peripheral circuit structure PC and the first to ith memory blocks BLK1 to BLKi disposed over a substrate SUB. The first to ith memory blocks BLK1 to BLKi may overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed through a selective epitaxial growth method.

The peripheral circuit structure PC may include the row decoder 130, the column decoder 150, the page buffer group 140, and the control circuit 180 which constitute a circuit for controlling the operations of the first to ith memory blocks BLK1 to BLKi. For example, the peripheral circuit structure PC may include an NMOS transistor, a PMOS transistor, a resistor, and a capacitor that are electrically coupled to the first to ith memory blocks BLK1 to BLKi. The peripheral circuit structure PC may be disposed between the substrate SUB and the first to ith memory blocks BLK1 to BLKi.

Each of the first to ith memory blocks BLK1 to BLKi may include a source structure, bit lines, cell strings that are electrically coupled to the source structure and the bit lines, word lines that are electrically coupled to the cell strings, and select lines that are electrically coupled to the cell strings. Each of the cell strings may include memory cells and select transistors that are coupled in series by a cell plug. Each of the select lines may serve as a gate electrode of a corresponding select transistor and each of the word lines may serve as a gate electrode of a corresponding memory cell.

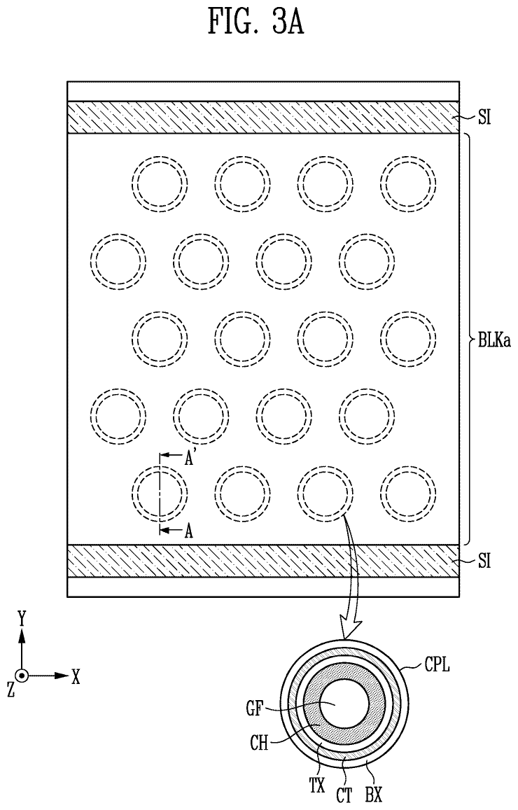

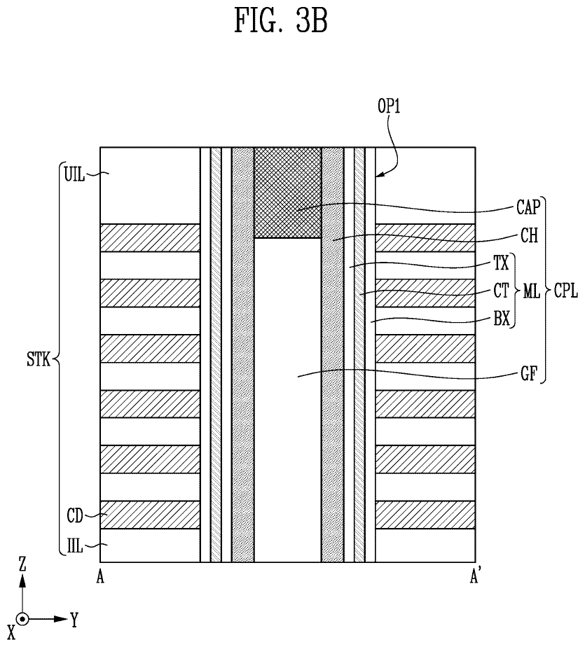

Each of the first to ith memory blocks BLK1 to BLKi may include a cell region and a contact region. At least a portion of cell plugs and dummy cell plugs may be formed in the cell region of each of the first to ith memory blocks BLK1 to BLKi. The cell plugs included in the first to ith memory blocks BLK1 to BLKi may correspond to the cell strings. The dummy cell plugs may have a similar structure to the cell plugs and might not correspond to the cell strings. Components in the cell region of each of the first to ith memory blocks BLK1 to BLKi will be described below with reference to FIGS. 3A and 3B.

A plurality of contacts may be formed in the contact region of each of the first to ith memory blocks BLK1 to BLKi. Each of the contacts may extend in a Z direction. For example, each of the contacts may include contact plugs each of which is electrically coupled to a corresponding one of the word lines and the select lines. In addition, the contact plugs may include contact plugs that are coupled to the peripheral circuit structure PC. Support structures may be disposed in the contact region of each of the first to ith memory blocks BLK1 to BLKi. Each of the support structures may extend in the Z direction.

In another embodiment, the substrate SUB, the peripheral circuit structure PC, and the first to ith memory blocks BLK1 to BLKi may be stacked in a reverse order with respect to the order shown in FIG. 2. For example, the peripheral circuit structure PC may be disposed over the first to ith memory blocks BLK1 to BLKi.

In another embodiment, apart from those shown in FIG. 2, the peripheral circuit structure PC may be disposed in an area of the substrate SUB that does not overlap the first to ith memory blocks BLK1 to BLKi. For example, the peripheral circuit structure PC and the first to ith memory blocks BLK1 to BLKi may be disposed over different areas of the substrate SUB that do not overlap each other.

FIG. 3A is a plan view of a layout of the memory device 100 according to an embodiment of the present disclosure.

Referring to FIG. 3A, the ath memory block BLKa (where a is a natural number, 1<a<i) and adjacent memory blocks may be separated from each other by slits SI. For example, the slits SI may be located in a Y direction with respect to the ath memory block BLKa or in an opposite direction to the Y direction with respect to the ath memory block BLKa. Each of the slits SI may extend in an X direction. The ath memory block BLKa may be adjacent to another memory block with each of the slits SI interposed therebetween.

The ath memory block BLKa may include a plurality of cell plugs CPL. For example, the cell plugs CPL may be formed in the cell region described with reference to FIG. 2. The cell plugs CPL may extend in the vertical direction (e.g., in the Z direction) from a substrate (not shown). The cell plugs CPL may be arranged in a plurality of rows. Each of the rows may include the cell plugs CPL that are spaced apart from each other in the X direction. The plurality of rows may be spaced apart from each other in the Y direction. The center of each of the cell plugs CPL included in an odd-numbered row and the center of each of the cell plugs CPL included in an even-numbered row may be offset from each other.

Each of the cell plugs CPL may include a blocking layer BX, a charge trap layer CT, a tunneling layer TX, a channel layer CH, and a gap-fill layer GF. The blocking layer BX may have a cylindrical shape. The charge trap layer CT may contact an inner side surface of the blocking layer BX. The tunneling layer TX may contact an inner side surface of the charge trap layer CT. The channel layer CH may contact an inner side surface of the tunneling layer TX. The gap-fill layer GF may fill in the channel layer CH. For example, the gap-fill layer GF may be formed to have a cylindrical shape in an area surrounded by the channel layer CH. Though not shown in FIG. 3A, a capping layer may further be formed over the gap-fill layer GF.

Each of the blocking layer BX and the tunneling layer TX may include an oxide layer (e.g., a silicon oxide layer), an oxynitride layer (e.g., a silicon oxynitride layer), or a combination thereof. The charge trap layer CT may include a nitride layer or a variable resistance material. The channel layer CH may include an undoped silicon layer or a doped silicon layer. The gap-fill layer GF may include an insulating layer or a conductive layer. Each of the blocking layer BX, the charge trap layer CT, the tunneling layer TX, the channel layer CH, and the gap-fill layer GF included in each of the cell plugs CPL may extend in the vertical direction (e.g., in the Z direction).

FIG. 3B is a cross-sectional view of the memory device 100 according to an embodiment of the present disclosure. FIG. 3B shows a cross-section taken along line A-A′ of FIG. 3A.

Referring to FIG. 3B, the memory device 100 (e.g., the ath memory block BLKa) may include a stack structure STK. The stack structure STK may include conductive layers CD and interlayer insulating layers IIL which are alternately stacked. The conductive layers CD and the interlayer insulating layers IIL may be alternately stacked in the Z direction. Each of the conductive layers CD may correspond to the drain select line DSL, the word line WL, or the source select line SSL in FIG. 1. The stack structure STK may further include an upper insulating layer UIL. The thickness of the upper insulating layer UIL may be greater than the thickness of each of the interlayer insulating layers IIL. For example, as shown in FIG. 3B, the thickness (i.e., the length in the Z direction) of the upper insulating layer UIL may be greater than the thickness (i.e., the length in the Z direction) of each of the interlayer insulating layers IIL.

The conductive layers CD may include at least one of tungsten (W), cobalt (Co), nickel (Ni), molybdenum (Mo), silicon (Si), and polysilicon (poly-Si). The interlayer insulating layers IIL may include an oxide layer. For example, the interlayer insulating layers IIL may include a silicon oxide layer. The upper insulating layer UIL may include the same material or the same type of material as the interlayer insulating layers IIL. For example, the upper insulating layer UIL may include a silicon oxide layer.

The memory device 100 (e.g., the ath memory block BLKa) may include the cell plug CPL. The cell plug CPL may extend in the vertical direction (e.g., in the Z direction) in the stack structure STK. The cell plug CPL may penetrate the stack structure STK. For example, the cell plug CPL may be located in a first opening OP1 penetrating the stack structure STK. The memory cells or the select transistors described with reference to FIGS. 1 and 2 may be respectively formed at intersections of the cell plug CPL and the conductive layers CD.

The cell plug CPL may include a memory layer ML. The memory layer ML may include the blocking layer BX, the charge trap layer CT, and the tunneling layer TX. The memory layer ML may penetrate the stack structure STK. The memory layer ML may be formed along an inner wall of the first opening OP1. For example, the blocking layer BX may contact an inner side surface of the first opening OP1. That is, the blocking layer BX may contact an inner side surface of the stack structure STK. The memory layer ML may extend on an outer wall of the channel layer CH. For example, the tunneling layer TX may contact an outer side surface of the channel layer CH.

The cell plug CPL may include the channel layer CH. The channel layer CH may penetrate the stack structure STK. The channel layer CH may extend in the Z direction. The channel layer CH may have a cylindrical shape.

The cell plug CPL may include the gap-fill layer GF. The gap-fill layer GF may be located in the channel layer CH. The gap-fill layer GF may contact an inner side surface of the channel layer CH. The gap-fill layer GF may be surrounded by the channel layer CH. The gap-fill layer GF may fill at least a portion of the area surrounded by the channel layer CH.

The cell plug CPL may include a capping layer CAP. The capping layer CAP may be disposed on the gap-fill layer GF. The capping layer CAP may contact the inner side surface of the channel layer CH. The capping layer CAP may be surrounded by the channel layer CH. The capping layer CAP may fill another portion of the area surrounded by the channel layer CH in which the gap-fill layer GF is not filled.

A lower surface of the capping layer CAP may be located at a level corresponding to the uppermost conductive layer CD among the conductive layers CD. That is, a level of an interface between the gap-fill layer GF and the capping layer CAP may correspond to a level at which the uppermost conductive layer CD is located. Unlike the embodiment shown in FIG. 3B, the capping layer CAP may be formed such that the lower surface of the capping layer CAP is located at a level which is higher or lower than that shown in FIG. 3B. The capping layer CAP may include the same material or the same type of material as the channel layer CH.

Apart from an embodiment shown in FIG. 3B, the stack structure STK may include a lower stack structure and an upper stack structure. The method in which the stack structure STK is divided into the upper stack structure and the lower stack structure may be referred to as a double stack method. When the stack structure STK includes the upper stack structure and the lower stack structure, the interlayer insulating layer IIL, which is located at an interface between the lower stack structure and the upper stack structure, may have a greater thickness than each of the remaining interlayer insulating layers IIL. In addition, when the stack structure STK includes the lower stack structure and the upper stack structure, the cell plug CPL may have a curvature at the interface between the lower stack structure and the upper stack structure. For example, the width of the cell plug CPL in the Y direction at the bottom of the upper stack structure may be smaller than the width of the cell plug CPL in the Y direction at the top of the lower stack structure.

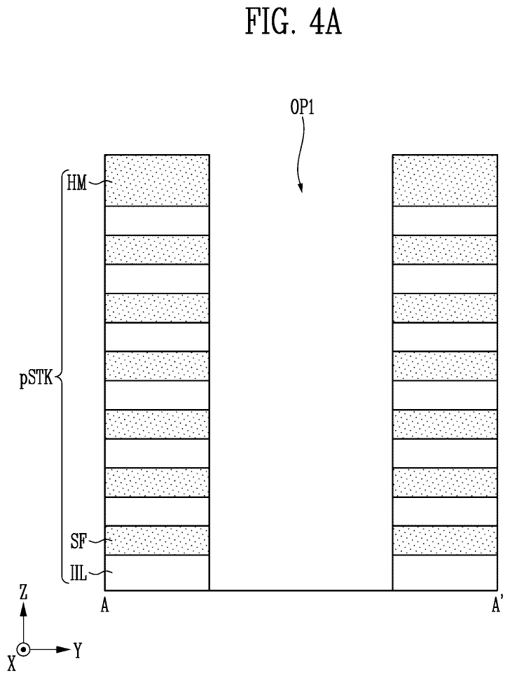

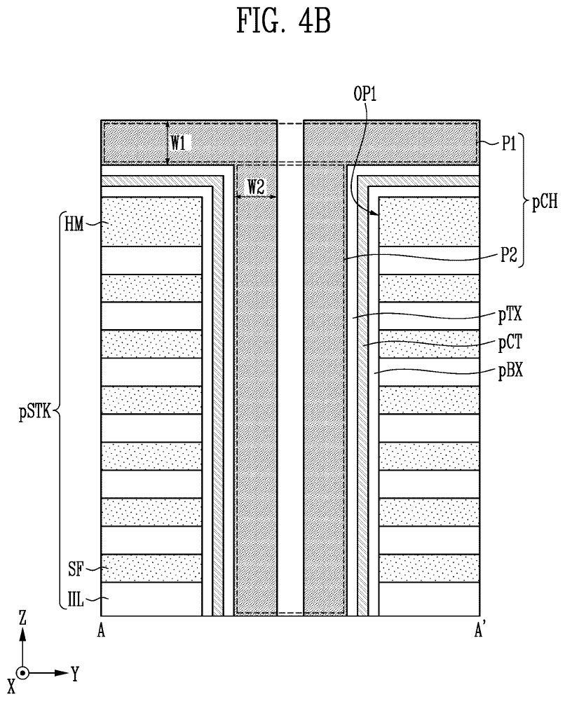

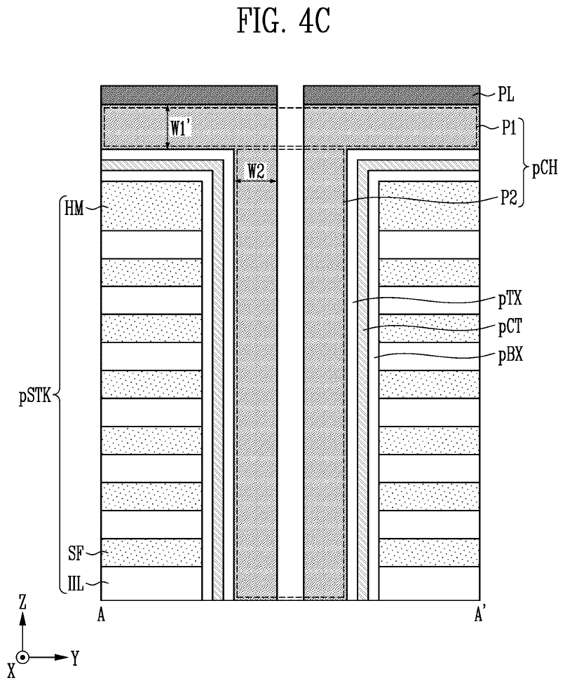

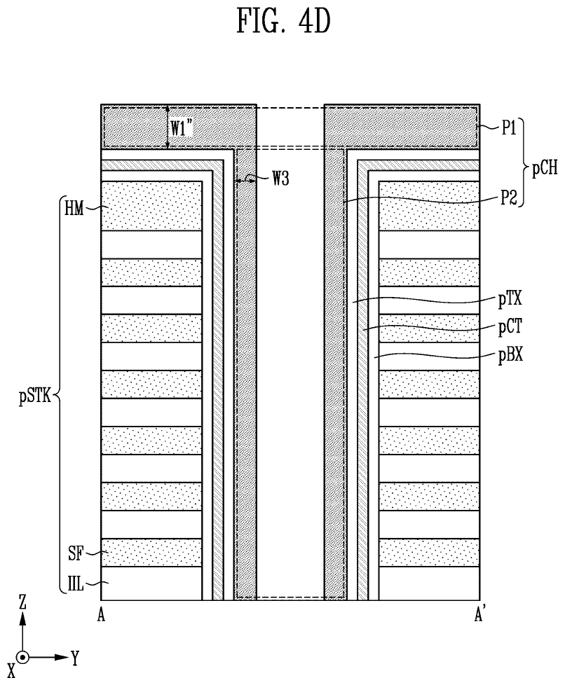

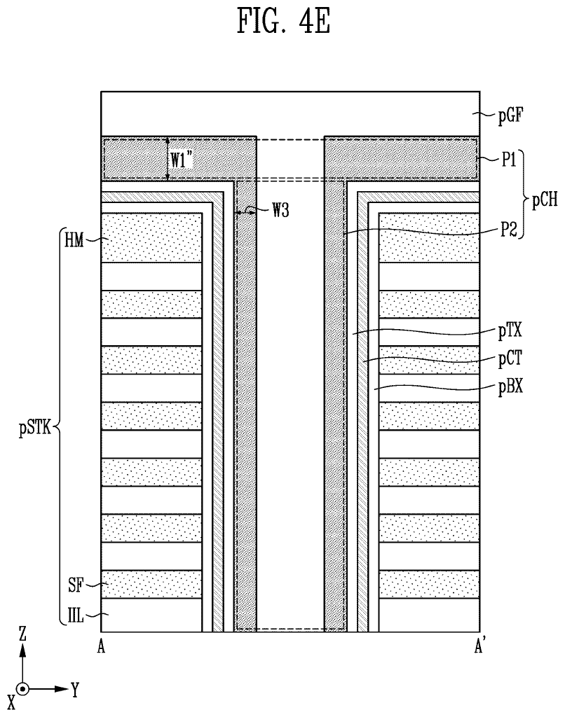

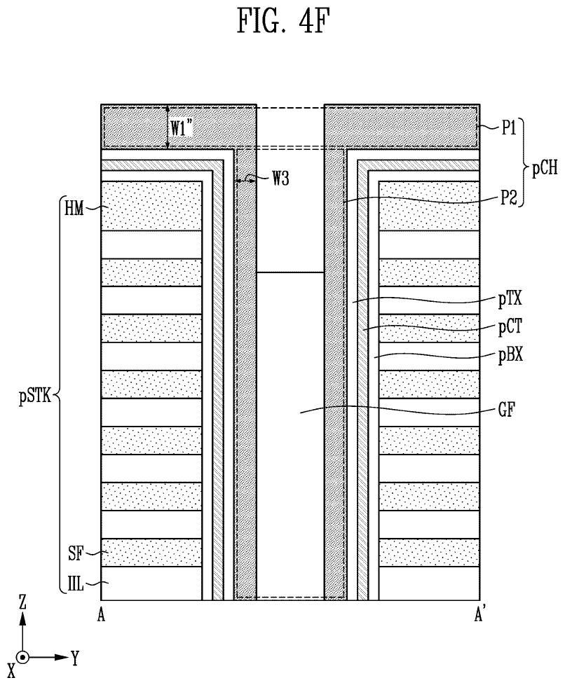

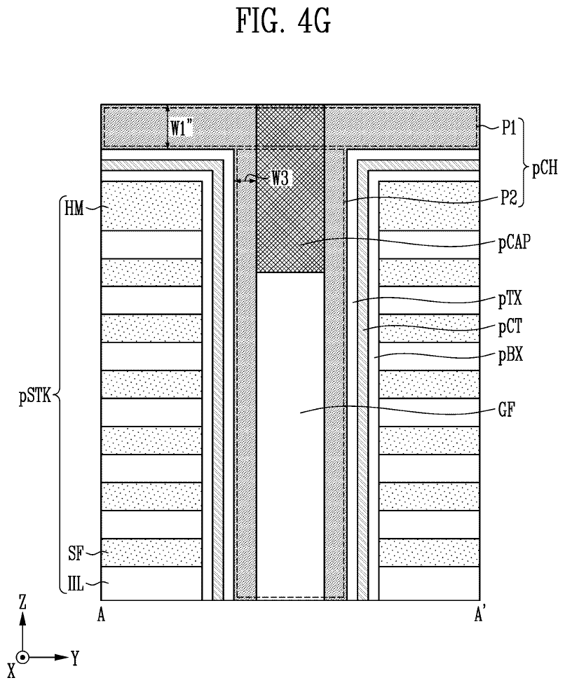

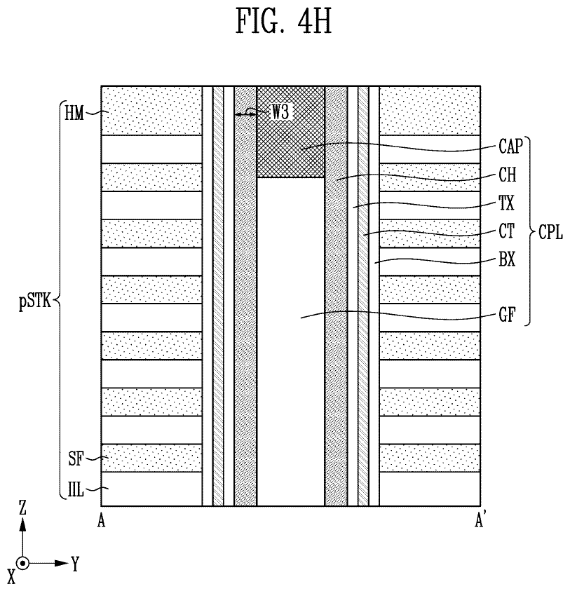

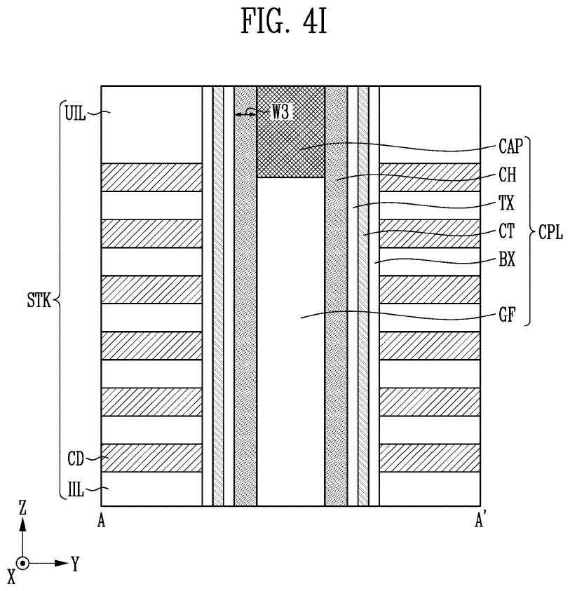

FIGS. 4A to 4I are diagrams illustrating a method of manufacturing the memory device 100 according to an embodiment of the present disclosure. FIGS. 4A to 4I each correspond to the A-A′ cross-section of FIG. 3A.

Referring to FIG. 4A, a preliminary stack structure pSTK may be formed. The preliminary stack structure pSTK may include first material layers IIL and second material layers SF that are alternately stacked in the Z direction. The first material layers IIL may include an insulating material. For example, the first material layers IIL may include an oxide layer (e.g., a silicon oxide layer). The first material layers IIL may be referred to as the interlayer insulating layers IIL. The second material layers SF may include a material that may be selectively removed in a subsequent process. Accordingly, the second material layers SF may include a material having a different etch selectivity from that of the first material layer IIL. For example, the second material layers SF may include a nitride layer. The preliminary stack structure pSTK may further include a hard mask HM. The hard mask HM may be located over the first and second material layers IIL and SF. The hard mask HM may have a greater thickness than each of the first and second material layers IIL and SF. For example, the height of the hard mask HM (e.g., the length in the Z direction) may be greater than the height of each of the second material layers SF (e.g., the length in the Z direction). The hard mask HM may include a nitride material.

Subsequently, the first opening OP1 penetrating the preliminary stack structure pSTK may be formed. The first opening OP1 may penetrate the hard mask HM, the first material layers IIL, and the second material layers SF of the preliminary stack structure pSTK. The first opening OP1 may extend in the Z direction. The first opening OP1 may have a hole shape.

Referring to FIG. 4B, a preliminary blocking layer pBX, a preliminary charge trap layer pCT, and a preliminary tunneling layer pTX may be formed over the preliminary stack structure pSTK. For example, the preliminary blocking layer pBX, the preliminary charge trap layer pCT, and the preliminary tunneling layer pTX may be sequentially formed along an upper surface of the preliminary stack structure pSTK and the inner side surface of the first opening OP1. For example, in an embodiment, the preliminary blocking layer pBX, the preliminary charge trap layer pCT, and the preliminary tunneling layer pTX may be sequentially formed along an upper surface of the preliminary stack structure pSTK and the inner side surface of the first opening OP1 as shown in FIG. 4B.

The preliminary blocking layer pBX, the preliminary charge trap layer pCT, and the preliminary tunneling layer pTX may be sequentially located in the first opening OP1. Each of the preliminary blocking layer pBX, the preliminary charge trap layer pCT, and the preliminary tunneling layer pTX may penetrate the preliminary stack structure pSTK.

Subsequently, a preliminary channel layer pCH may be formed over the preliminary stack structure pSTK. The preliminary channel layer pCH may be formed along a surface of the preliminary tunneling layer pTX. That is, the preliminary channel layer pCH may be formed along an inner side surface and the upper surface of the preliminary stack structure pSTK. The preliminary channel layer pCH may be formed through a deposition process. For example, the preliminary channel layer pCH may be formed by a process of depositing polysilicon on the preliminary tunneling layer pTX.

The preliminary channel layer pCH may include a first part P1 located over the preliminary stack structure pSTK and a second part P2 located in the first opening OP1. The first part P1 of the preliminary channel layer pCH may extend on the upper surface of the preliminary stack structure pSTK. That is, the first part P1 may have a plate shape which extends in the X and Y directions. For example, the first part P1 of the preliminary channel layer pCH may extend on the upper surface of the preliminary stack structure pSTK as shown in FIG. 4B. The second part P2 of the preliminary channel layer pCH may extend on an inner side surface of the first opening OP1. For example, the second part P2 of the preliminary channel layer pCH may extend on an inner side surface of the first opening OP1 as shown in FIG. 4B. That is, the second part P2 may have a cylindrical shape which extends in the Z direction. The second part P2 may extend in the vertical direction (e.g., in an opposite direction from the Z direction) from the first part P1. The first part P1 may contact an upper surface of the preliminary tunneling layer pTX and the second part P2 may contact an inner side surface of the preliminary tunneling layer pTX. In the present disclosure, it is described that the preliminary channel layer pCH is divided into the first part P1 and the second part P2 for convenience of description, but the first part P1 and the second part P2 might not be physically separated from each other or might not have a boundary therebetween in actual processes.

The first part P1 of the preliminary channel layer pCH may have a first thickness W1. The second part P2 of the preliminary channel layer pCH may have a second thickness W2. The first thickness W1 may be equal to or greater than the second thickness W2. For example, because the first part P1 and the second part P2 are formed through a single process, the first thickness W1 and the second thickness W2 may have substantially equal values. Alternatively, even when the thicknesses of the first part P1 and the second part P2 are different, the difference is caused by the characteristics of the deposition process. Therefore, in an embodiment, the difference between the first thickness W1 and the second thickness W2 might not be significant.

According to an embodiment of the present disclosure, the thickness of the first part P1 may correspond to the length in the vertical direction (e.g., in the Z direction) and the thickness of the second part P2 may correspond to the length in the horizontal direction (e.g., in the X or Y direction). That is, the thickness of the preliminary channel layer pCH may refer to the length in the direction in which the preliminary channel layer pCH is deposited.

Referring to FIG. 4C, a protective layer PL which covers the first part P1 of the preliminary channel layer pCH may be formed. The protective layer PL may contact an upper surface of the first part P1. The protective layer PL may selectively cover the first part P1. The protective layer PL may be formed on an upper surface of the preliminary channel layer pCH and might not be formed on an inner side surface of the preliminary channel layer pCH. For example, the protective layer PL might not cover an inner side surface of the second part P2. Accordingly, the second part P2 may remain exposed externally even after the protective layer PL is formed. In addition, the protective layer PL might not cover an inner side surface of the first part P1. Accordingly, the inner side surface of the first part P1 may remain exposed externally even after the protective layer PL is formed.

In an embodiment, the protective layer PL may be formed by a process of depositing a nitride material on the first part P1 of the preliminary channel layer pCH. For example, the nitride material is selectively deposited onto the upper surface of the first part P1 to form the protective layer PL. When the protective layer PL is deposited on the first part P1, a first thickness W1′ of the first part P1 may be equal to the first thickness W1.

In another embodiment, the protective layer PL may be formed through a process of nitriding the first part P1 of the preliminary channel layer pCH. For example, when a nitriding gas is supplied with plasma on the first part P1, a portion of the first part P1 may be nitrided to form the protective layer PL. Because the portion of the first part P1 is changed into the protective layer PL, the first part P1 may have a reduced first thickness W1′ which is smaller than the first thickness W1.

In addition, the protective layer PL may be formed through various processes for selectively covering the first part P1 between the first part P1 and the second part P2. In an embodiment, the protective layer PL may be formed through various processes and may be located on the first part P1.

In an embodiment, an annealing process of the preliminary channel layer pCH may be performed after the protective layer PL is formed. Through the annealing process, a grain boundary of the polysilicon included in the preliminary channel layer pCH may be reduced. The annealing process may be a process of performing a high-temperature treatment above a specific temperature for a predetermined period to the preliminary stack structure pSTK with the preliminary channel layer pCH. In another embodiment, the annealing process may be performed before the protective layer PL is formed. The word “predetermined” as used herein with respect to a parameter, such as a predetermined period, predetermined depth, or predetermined thickness, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

Referring to FIG. 4D, a portion of the preliminary channel layer pCH may be etched. For example, an isotropic wet etching process using a material that selectively etches a polysilicon material may be performed. Because the protective layer PL includes a material (e.g., a nitride material) having etch selectivity to polysilicon, the etching speed of the protective layer PL may be lower than the etching speed of the preliminary channel layer pCH.

A portion of the second part P2 which is not covered by the protective layer PL may be etched by the etching process. Because the inner side surface of the second part P2 is not covered by the protective layer PL and exposed externally, the portion of the second part P2 may be removed. Because the etching process starts from the inner side surface of the second part P2, the thickness of the second part P2 may be reduced. The etched second part P2 may have a third thickness W3 which is smaller than the second thickness W2. The third thickness W3 may be smaller than each of the first thickness W1 in FIG. 4B and the first thickness W1′ in FIG. 4C.

Because the upper surface of the first part P1 is covered by the protective layer PL, when the portion of the second part P2 is etched, the first part P1 might not be etched or may be etched less than the second part P2. Accordingly, the first part P1 may have a greater thickness than the second part P2. A first thickness W1″ of the first part P1 may be greater than the third thickness W3 of the second part P2.

In an embodiment, when the second part P2 is etched, the protective layer PL may be removed. Because the etching speed of the protective layer PL is lower than the etching speed of the preliminary channel layer pCH, the thickness of the etched portion of the first part P1 may be smaller than the thickness of the etched portion of the second part P2. Accordingly, the first thickness W1″ of the first part P1 may be smaller than or equal to the first thickness W1′ in FIG. 4C.

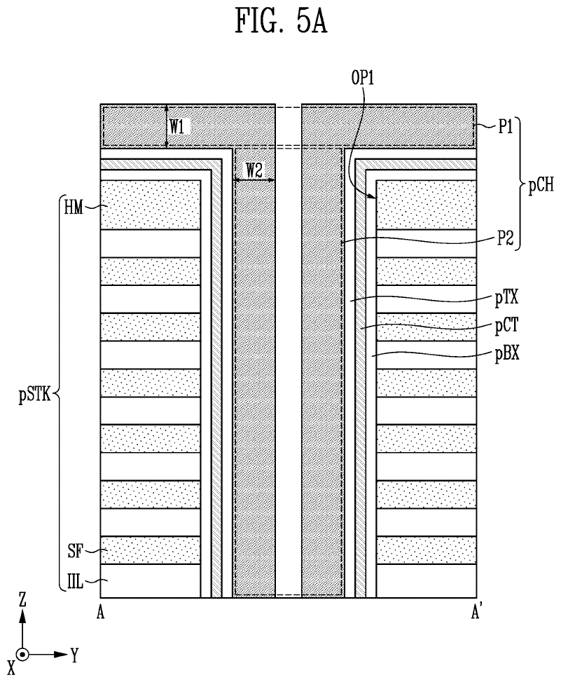

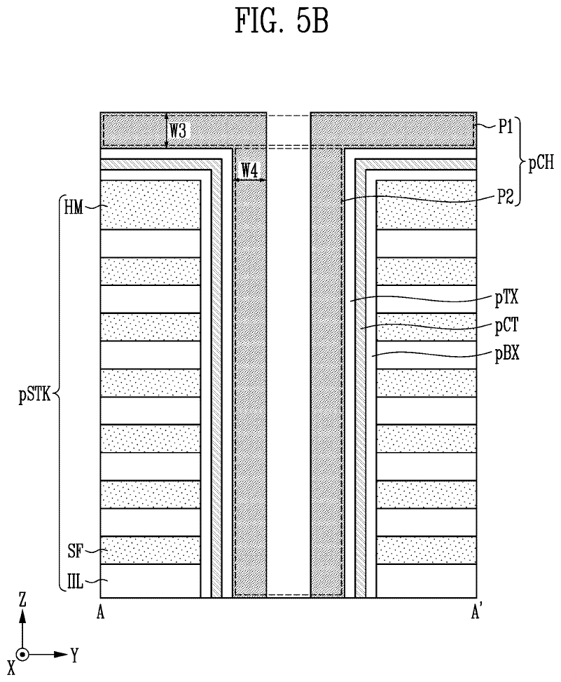

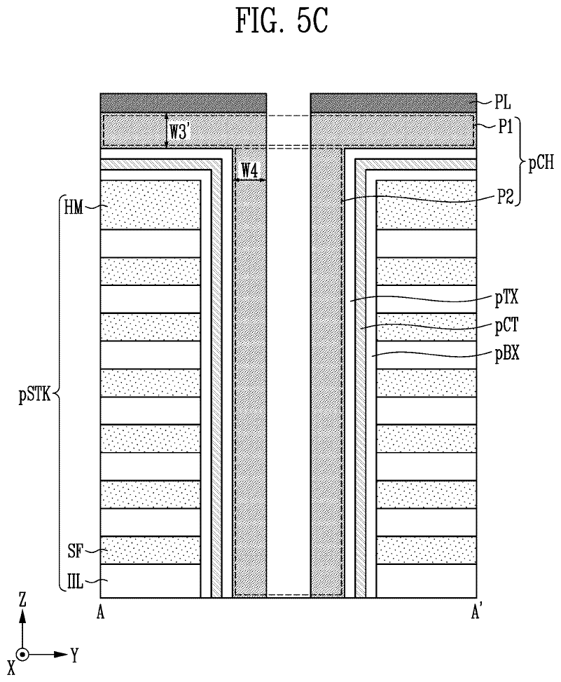

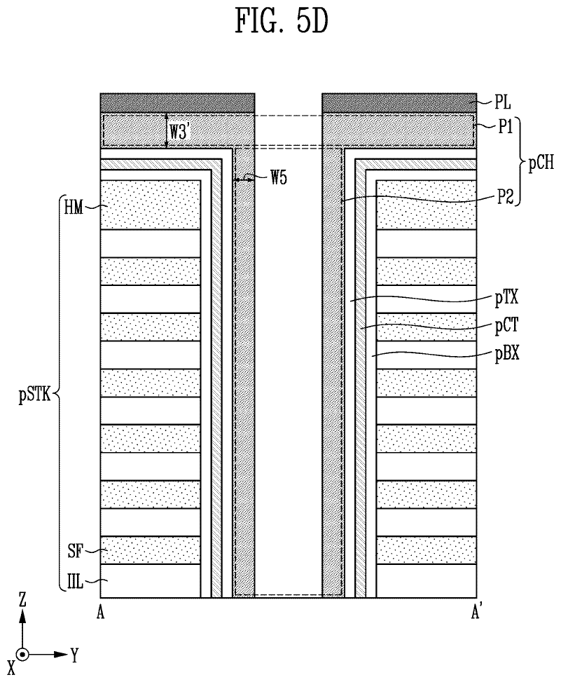

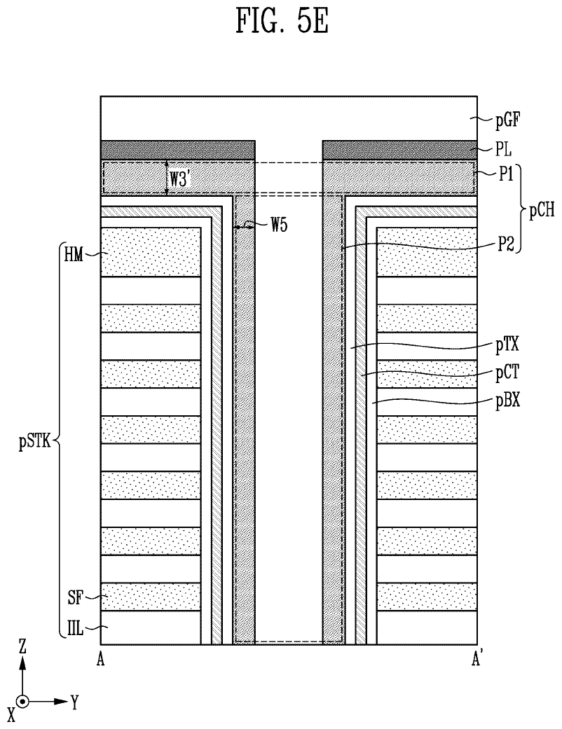

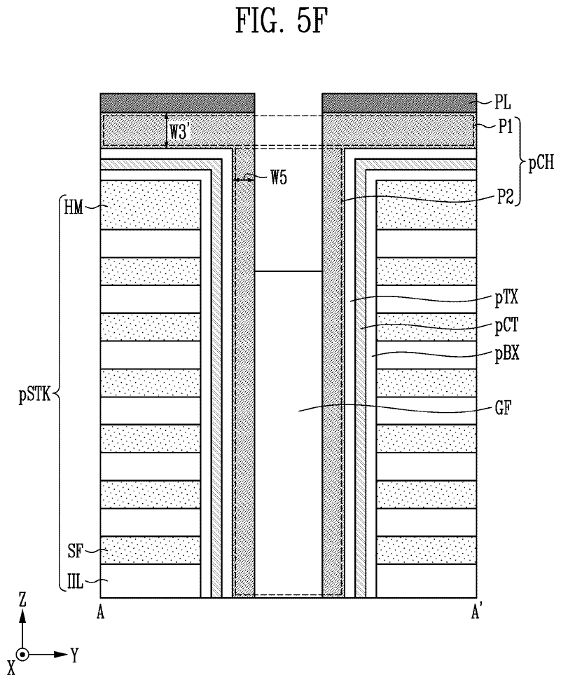

In another embodiment, apart from the embodiment shown in FIG. 4D, when the portion of the second part P2 is removed, the protective layer PL might not be removed and may remain. For example, when the preliminary channel layer pCH is etched, the protective layer PL might not be etched or a portion of the protective layer PL may be etched and the rest of the protective layer PL may remain. When the protective layer PL remains, the first part P1 may be covered by the protective layer PL. Accordingly, when the protective layer PL is not removed, the first part P1 might not be etched or only etched to a negligibly small amount. In an embodiment in which the first part P1 is not etched, the first thickness W1″ of the first part P1 may be equal to the first thickness W1′ in FIG. 4C. An embodiment in which the protective layer PL remains will be described below with reference to FIG. 5D.

In some embodiments, the difference in thickness between the first part P1 and the second part P2 exists even when the protective layer PL remains. In other embodiments, the difference in thickness between the first part P1 and the second part P2 exists even when the protective layer PL does not remain. That is, for various embodiments, regardless of whether the protective layer PL remains or not, a difference in thickness between the first part P1 and the second part P2 exists.

However, because the inner side surface of the first part P1 is not covered by the protective layer PL and is exposed externally, the inner side surface of the first part P1 may be etched along with the inner side surface of the second part P2.

Referring to FIG. 4E, a preliminary gap-fill layer pGF filling the first opening OP1 and extending over the preliminary stack structure pSTK may be formed. A portion of the preliminary gap-fill layer pGF may be located in the first opening OP1. The portion of the preliminary gap-fill layer pGF may be surrounded by the preliminary channel layer pCH. The preliminary gap-fill layer pGF may contact the inner side surface of the preliminary channel layer pCH. For example, the preliminary gap-fill layer pGF may contact the inner side surface of the first part P1 and the inner side surface of the second part P2. Another portion of the preliminary gap-fill layer pGF may be formed over the preliminary stack structure pSTK. For example, the preliminary gap-fill layer pGF may contact the upper surface of the first part P1.

Referring to FIG. 4F, the portion of the preliminary gap-fill layer pGF may be etched to form the gap-fill layer GF. A portion of the inner side surface of the preliminary channel layer pCH may be exposed because the portion of the preliminary gap-fill layer pGF is removed. For example, an upper part of the second part P2 may be exposed externally over the gap-fill layer GF or the inner side surface of the first part P1 may be exposed externally. In an embodiment, the portion of the inner side surface of the second part P2 that has been exposed by the portion of the preliminary gap-fill layer pGF being removed may be referred to as an upper part of the second part P2.

In order to etch the preliminary gap-fill layer pGF to a predetermined depth, an anisotropic dry etching process may be performed. When the dry etching process is performed, an upper part of the preliminary stack structure pSTK may be protected by the first part P1. Because the first part P1 has the first thickness W1″ which is greater than that of the second part P2, the first part P1 may be sufficient to protect the preliminary stack structure pSTK when the dry etching process for etching the preliminary gap-fill layer pGF is performed. For example, in an embodiment, the preliminary stack structure pSTK is prevented from or mitigated from being etched by the first part P1 during the etching of the preliminary gap-fill layer GF.

Referring to FIG. 4G, a preliminary capping layer pCAP may be formed on the gap-fill layer GF. The preliminary capping layer pCAP may contact the preliminary channel layer pCH. The preliminary capping layer pCAP may fill the first opening OP1. Apart from an embodiment shown in FIG. 4G, the preliminary capping layer pCAP may extend over the preliminary stack structure pSTK.

Referring to FIG. 4H, the first part P1 of the preliminary channel layer pCH may be removed. In addition, a portion of the second part P2 of the preliminary channel layer pCH may be removed. Accordingly, the channel layer CH may have a cylindrical shape which extends in the Z direction in the preliminary stack structure pSTK.

In addition, a portion of the preliminary tunneling layer pTX, a portion of the preliminary charge trap layer pCT, and a portion of the preliminary blocking layer pBX located over the preliminary stack structure pSTK may be removed. For example, a portion of the preliminary tunneling layer pTX, a portion of the preliminary charge trap layer pCT, and a portion of the preliminary blocking layer pBX located over (i.e., in the Z direction) the preliminary stack structure pSTK may be removed as shown in FIG. 4H. Accordingly, the upper surface of the preliminary stack structure pSTK may be exposed. For example, an upper surface of the hard mask HM may be exposed. In addition, a portion of the preliminary capping layer pCAP which is located at a higher level than the upper surface of the preliminary stack structure pSTK may also be removed. [Original paragraph 81, Clarifying amendments were made to clarify and support the feature “removing a portion of the blocking layer, a portion of the charge trap layer, and a portion of the tunneling layer located over the stack structure” found in claim 12.

The blocking layer BX, the charge trap layer CT, the tunneling layer TX, the channel layer CH, the gap-fill layer GF, and the capping layer CAP, which are formed by removing material layers over the preliminary stack structure pSTK, may form the cell plug CPL. The channel layer CH included in the cell plug CPL may have the third thickness W3.

Referring to FIG. 4I, the stack structure STK may be formed by replacing the second material layers SF with third material layers CD and the hard mask HM with an oxide material. The third material layers CD may include a conductive material. The oxide material which replaces the hard mask HM and the uppermost interlayer insulating layer IIL in FIG. 4H may form the upper insulating layer UIL in FIG. 4I.

According to an embodiment of the present disclosure, the defects in the memory device 100 may be reduced by complementing the process that decreases the thickness of the channel layer CH. As the thickness of the channel layer CH included in the cell plug CPL decreases, the interference between the adjacent memory cells in the Z direction may be reduced. According to an embodiment of the present disclosure, the thickness of the channel layer CH may be reduced to the third thickness W3 by etching the portion of the second part P2 of the preliminary channel layer pCH. When the thicknesses of both of the first part P1 and the second part P2 of the preliminary channel layer pCH are reduced, defects may occur in the upper part of the preliminary stack structure pSTK in a subsequent dry etching process. However, according to an embodiment of the present disclosure, the first part P1 may have the first thickness W1″ which is greater than the third thickness W3 of the second part P2 by using the protective layer PL, thereby preventing or reducing the occurrence of defects in the preliminary stack structure pSTK when the dry etching process to etch the preliminary gap-fill layer pGF is performed.

FIGS. 5A to 5F are diagrams illustrating a method of manufacturing a memory device according to another embodiment of the present disclosure. FIGS. 5A to 5F each correspond to the A-A′ cross-section of FIG. 3A. In connection with FIGS. 5A to 5F, a detailed description of the configurations that have already been described with reference to FIGS. 4A to 4i will be omitted or simplified.

Referring to FIG. 5A, the preliminary channel layer pCH may be formed along the upper surface of the preliminary stack structure pSTK and the inner side surface of the first opening OP1. The preliminary channel layer pCH may include the first part P1 extending over the upper surface of the preliminary stack structure pSTK and the second part P2 extending over the inner side surface of the first opening OP1. The first part P1 may have the first thickness W1. The second part P2 may have the second thickness W2. The first thickness W1 may be equal to or greater than the second thickness W2.

Referring to FIG. 5B, the portion of the preliminary channel layer pCH may be etched. In order to reduce the thickness of the preliminary channel layer pCH, an isotropic wet etching process may be performed. The first part P1 of the preliminary channel layer pCH may have the third thickness W3 which is smaller than the first thickness W1, and the second part P2 of the preliminary channel layer pCH may have a fourth thickness W4 which is smaller than the second thickness W2. The third thickness W3 may be equal to or greater than the fourth thickness W4.

Referring to FIG. 5C, the protective layer PL which covers the first part P1 of the preliminary channel layer pCH may be formed. The protective layer PL may contact the upper surface of the first part P1. The protective layer PL may selectively cover the first part P1. The protective layer PL may be formed on the upper surface of the preliminary channel layer pCH and might not be formed on the inner side surface of the preliminary channel layer pCH. For example, the protective layer PL might not cover the inner side surface of the second part P2. Accordingly, even after the protective layer PL is formed, the second part P2 may remain exposed externally. In addition, the protective layer PL might not cover the inner side surface of the first part P1. Consequently, the inner side surface of the first part P1 may be exposed externally after the protective layer PL is formed.

The protective layer PL may be formed through processes such as the process explained with reference to FIG. 4C. For example, the protective layer PL may be formed through a process of nitriding the first part P1 of the preliminary channel layer pCH, a process of depositing a nitride material onto the first part P1 of the preliminary channel layer pCH, or through various other methods. After the protective layer PL is formed, the first part P1 may have a third thickness W3′ that is reduced from or equal to the third thickness W3.

Referring to FIG. 5D, the portion of the preliminary channel layer pCH may be etched. For example, an isotropic wet etching process using a material that selectively etches a polysilicon material may be performed. The portion of the second part P2 which is not covered by the protective layer PL may be etched by the etching process. Because the inner side surface of the second part P2 is not covered by the protective layer PL and exposed externally, the portion of the second part P2 may be removed. Because the etching process starts from the inner side of the second part P2, the thickness of the second part P2 may be reduced. The etched second part P2 may have a fifth thickness W5 which is smaller than the fourth thickness W4.

Because the upper surface of the first part P1 is covered by the protective layer PL, when the portion of the second part P2 is etched, the first part P1 might not be etched or may be etched less than the second part P2. Accordingly, the first part P1 may have a greater thickness than the second part P2. The third thickness W3′ of the first part P1 may be greater than the fifth thickness W5 of the second part P2. The third thickness W3′ of the first part P1 in FIG. 5D may be smaller than or equal to the third thickness W3′ in FIG. 5C.

As described with reference to FIG. 4D, when the portion of the second part P2 is etched, the protective layer PL might not be removed and may remain. For example, the etching process uses a material that selectively etches the preliminary channel layer pCH, the protective layer PL might not be etched and may remain. In another example, because the etching speed of the protective layer PL is lower than that of the preliminary channel layer pCH, the protective layer PL of which a portion is etched may remain on the preliminary stack structure pSTK. When the portion of the protective layer PL is etched, the thickness of the protective layer PL in FIG. 5D may be smaller than the thickness of the protective layer PL in FIG. 5C.

In another embodiment, the protective layer PL may be removed when the portion of the second part P2 is etched. The etching speed of the protective layer PL is lower than that of the preliminary channel layer pCH. Therefore, even when the protective layer PL is removed, the thickness of the etched portion of the first part P1 may be smaller than the thickness of the etched portion of the second part P2.

In some embodiments, the difference in thickness between the first part P1 and the second part P2 exists even when the protective layer PL remains. In other embodiments, the difference in thickness between the first part P1 and the second part P2 exists even when the protective layer PL does not remain. That is, for various embodiments, regardless of whether the protective layer PL remains or not, a difference in thickness between the first part P1 and the second part P2 exists.

Referring to FIG. 5E, the preliminary gap-fill layer pGF filling the first opening OP1 and extending over the preliminary stack structure pSTK may be formed. The preliminary gap-fill layer pGF may contact the preliminary channel layer pCH and the protective layer PL.

Referring to FIG. 5F, the portion of the preliminary gap-fill layer pGF may be etched to form the gap-fill layer GF which exposes an upper part of the preliminary channel layer pCH. Because the portion of the preliminary gap-fill layer pGF is removed, the inner side surface of the first part P1 of the preliminary channel layer pCH may be exposed and an upper part of the inner side surface of the second part P2 may be exposed.

In order to etch the preliminary gap-fill layer pGF to a predetermined depth, an anisotropic dry etching process may be performed. When the dry etching process is performed, the upper part of the preliminary stack structure pSTK may be protected by at least one of the protective layer PL or the first part P1. Because the first part P1 has the third thickness W3′ which is greater than that of the second part P2, the first part P1 may be sufficient to protect the preliminary stack structure pSTK when the dry etching process for etching the preliminary gap-fill layer pGF is performed.

After the process illustrated in FIG. 5F, processes corresponding to those described with reference to FIGS. 4G to 4I may be performed.

Compared to the embodiments described with reference to FIGS. 4A to 4I, the embodiments described with reference to FIGS. 5A to 5F may further include the process illustrated in FIG. 5B. When the thickness of the preliminary channel layer pCH is greater than a predetermined thickness, defects (e.g., voids) may occur during the formation of the preliminary gap-fill layer pGF. Accordingly, an additional etching process may be performed to reduce the overall thickness of the preliminary channel layer pCH before the formation of the protective layer PL to prevent the defects (e.g., voids).

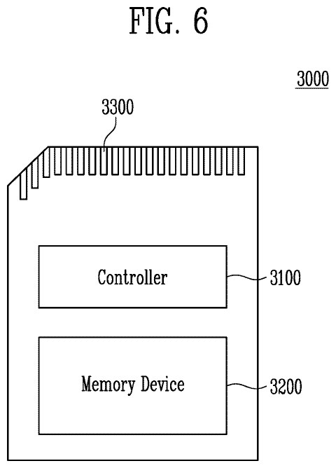

FIG. 6 is a diagram illustrating a memory card system 3000 to which a memory device according to an embodiment of the present disclosure is applied.

Referring to FIG. 6, the memory card system 3000 may include a controller 3100, a memory device 3200, and a connector 3300.

The controller 3100 may be coupled to the memory device 3200. The controller 3100 may be configured to access the memory device 3200. For example, the controller 3100 may be configured to control a program operation, a read operation, or an erase operation of the memory device 3200, or control a background operation. The controller 3100 may be configured to provide an interface between the memory device 3200 and a host. The controller 3100 may be configured to drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1. For example, the plurality of memory cells may be stacked in the vertical direction.

The controller 3100 and the memory device 3200 may be integrated into a single semiconductor device to constitute a memory card. For example, the controller 3100 and the memory device 3200 may be integrated into a single semiconductor device to constitute a memory card such as a personal computer (PC) card in the form of a Personal Computer Memory Card International Association (PCMCIA) card, a Compact Flash (CF) card, a Smart Media Card (SM and SMC), a memory stick, a Multi-Media Card (MMC, RS-MMC, MMCmicro, or eMMC), a Secure Digital (SD) card (SD, miniSD, microSD, or SDHC), and a Universal Flash Storage (UFS).

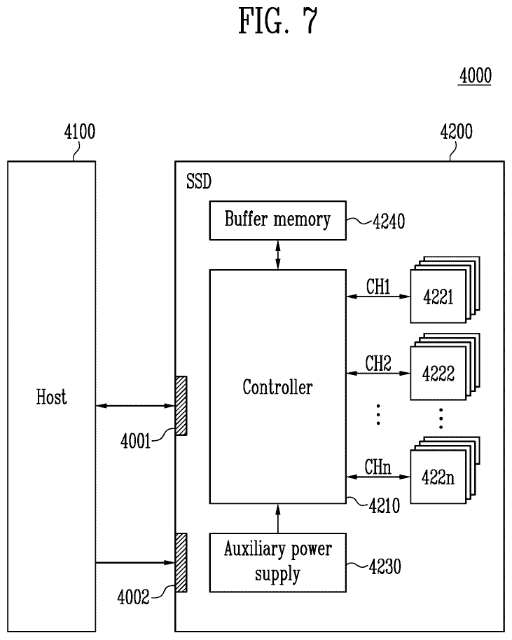

FIG. 7 is a diagram illustrating a solid state drive (SSD) system 4000 to which a memory device according to an embodiment of the present disclosure is applied.

Referring to FIG. 7, the SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one of interfaces such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe interfaces.

Th The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive and be charged with a power voltage from the host 4100. When the supply of power from the host 4100 is not smooth, the auxiliary power supply 4230 may provide a power voltage of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to various embodiments of the present disclosure, the defects in a memory block may be reduced by complementing the process that decreases the thickness of a channel layer.

What is claimed is:

1. A method of manufacturing a memory device, the method comprising:
forming an opening penetrating a stack structure;
forming a channel layer including a first part and a second part, wherein the first part extends on an upper surface of the stack structure and has a first thickness, and the second part extends on an inner side surface of the opening and has a second thickness;
forming a protective layer on the first part of the channel layer; and
etching a portion of the second part so that the second part has a third thickness less than the second thickness,
wherein the third thickness of the second part is less than the first thickness of the first part.

2. The method of claim 1, wherein in the forming of the protective layer, the protective layer does not cover an inner side surface of the second part.

3. The method of claim 2, wherein in the etching of the portion of the second part, the inner side surface of the second part which is not covered by the protective layer is etched.

4. The method of claim 1, further comprising, after etching the portion of the second part:
forming a preliminary gap-fill layer filling the opening and extending over the stack structure; and
forming a gap-fill layer by etching a portion of the preliminary gap-fill layer, wherein the gap-fill layer exposes an upper part of the second part,
wherein the stack structure is prevented from being etched by the first part when the portion of the preliminary gap-fill layer is etched.

5. The method of claim 4, further comprising, after forming the gap-fill layer:
forming a capping layer over the gap-fill layer; and
removing the first part of the channel layer.

6. The method of claim 1, wherein in the forming of the protective layer, the protective layer includes a nitride material.

7. The method of claim 1, wherein in the etching of the portion of the second part, the protective layer is removed.

8. The method of claim 1, wherein in the etching of the portion of the second part, the protective layer remains, and the protective layer is not removed.

9. The method of claim 1, wherein in the etching of the portion of the second part, the protective layer has an etching speed that is slower than an etching speed of the second part.

10. The method of claim 1, further comprising, before forming the opening, forming the stack structure including sacrificial layers and interlayer insulating layers which are alternately stacked.

11. The method of claim 10, further comprising, before forming the channel layer, forming a blocking layer, a charge trap layer, and a tunneling layer sequentially over the upper surface of the stack structure and the inner side surface of the opening.

12. The method of claim 11, further comprising, after etching the portion of the second part:
forming a gap-fill layer and a capping layer in the opening;
removing the protective layer and the first part of the channel layer; and
removing a portion of the blocking layer, a portion of the charge trap layer, and a portion of the tunneling layer located over the stack structure.

13. The method of claim 12, further comprising, after removing the protective layer, the first part of the channel layer, the portion of the blocking layer, the portion of the charge trap layer, and the portion of the tunneling layer, replacing the sacrificial layers of the stack structure with conductive layers.

14. The method of claim 1, wherein in the forming of the protective layer, the protective layer covers less than all of an inner side surface of the second part.

15. A method of manufacturing a memory device, the method comprising:
forming an opening penetrating a stack structure;
forming a channel layer including a first part and a second part, wherein the first part extends on an upper surface of the stack structure and the second part extends on an inner side surface of the opening;
forming a protective layer on the first part of the channel layer; and
etching a portion of the second part which is not covered by the protective layer so that the second part has a smaller thickness than the first part.

16. The method of claim 15, wherein in the forming of the channel layer:
the first part has a first thickness;
the second part has a second thickness; and
the first thickness is greater than or equal to the second thickness.

17. The method of claim 16, further comprising, after forming the channel layer, etching a portion of the channel layer so that the first part has a third thickness smaller than the first thickness and the second part has a fourth thickness smaller than the second thickness.

18. The method of claim 17, wherein in the etching of the portion of the channel layer, the third thickness is greater than or equal to the fourth thickness.

19. The method of claim 17, wherein in the forming of the protective layer, the protective layer is formed over the first part having the third thickness.

20. The method of claim 17, wherein in the etching of the portion of the second part:
the portion of the second part is etched so that the second part has a fifth thickness smaller than the fourth thickness, and
the first part remains and has the third thickness due to the protective layer when the portion of the second part is etched.

21. The method of claim 15, wherein in the forming of the protective layer, the protective layer does not cover an inner side surface of the second part.

22. The method of claim 21, wherein in the etching of the portion of the second part, the inner side surface of the second part which is not covered by the protective layer is etched.

23. The method of claim 15, further comprising, after etching the portion of the second part:
forming a preliminary gap-fill layer filling the opening and extending over the stack structure; and
forming a gap-fill layer by etching a portion of the preliminary gap-fill layer, wherein the gap-fill layer exposes an upper part of the second part,
wherein the stack structure is prevented from being etched by the first part when the portion of the preliminary gap-fill layer is etched.

24. The method of claim 23, further comprising, after forming the gap-fill layer:
forming a capping layer over the gap-fill layer; and
removing the protective layer and the first part of the channel layer.
